(19) United States
(12) Patent Application Publication
(10) Pub. No.: US 2015/0123278 A1
(43) Pub. Date: May 7, 2015

(54) SEMICONDUCTOR DEVICES, METHODS OF MANUFACTURING THE SAME, MEMORY CARDS INCLUDING THE SAME AND ELECTRONIC SYSTEMS INCLUDING THE SAME

(71) Applicant: SK HYNIX INC., Icheon (KR)

(72) Inventors: Sung Su PARK, Yongin (KR); Jong Kyu MOON, Icheon (KR); Wan Choon PARK, Icheon (KR); Bae Yong KIM, Haenam-gun (KR)

(73) Assignee: SK HYNIX INC., Icheon (KR)

(21) Appl. No.: 14/247,049

(22) Filed: Apr. 7, 2014

(30) Foreign Application Priority Data
Nov. 7, 2013 (KR) 10-2013-0134855

(51) Int. Cl. H01L 23/48

(52) U.S. Cl. CPC H01L 23/481
USPC 257/751; 257/774

(57) ABSTRACT

Semiconductor devices are provided. The semiconductor device includes a through electrode penetrating a substrate such that an end portion of the through electrode protrudes from a surface of the substrate, a passivation layer covering the surface of the substrate and defining a plug hole that exposes the end portion of the through electrode, and a barrier plug filling the plug hole. Related methods, related memory cards and related electronic systems are also provided.

### CROSS-REFERENCE TO RELATED APPLICATION

The present application claims priority under 35 U.S.C. 119(a) to Korean Application No. 10-2013-0134855, filed on Nov. 7, 2013, in the Korean intellectual property Office, which is incorporated herein by reference in its entirety as set forth in full.

### BACKGROUND

1. Technical Field

Embodiments of the present disclosure relate to package technologies, and more particularly, to semiconductor devices having through via structures, methods of manufacturing the same, memory cards including the same and electronic systems including the same.

2. Related Art

Semiconductor devices employed in electronic systems may include various electronic circuit elements, and the electronic circuit elements may be integrated in and/or on a semiconductor substrate to constitute the semiconductor device (also referred to as a semiconductor chip or a semiconductor die). Memory semiconductor chips may be employed in electronic systems. Before semiconductor devices including memory semiconductor chips are employed in the electronic systems, the semiconductor devices may be encapsulated to have package forms. These semiconductor packages may be employed in the electronic systems, for example, computers, mobile systems or data storage media.

As the mobile systems such as smart phones become lighter and smaller, the semiconductor packages employed in mobile systems have been continuously scaled down. In addition, large capacitive semiconductor packages are increasingly in demand with the development of multi-functional mobile systems. In this connection, many efforts to put a plurality of semiconductor devices in a single package have been attempted to provide the large capacitive semiconductor packages such as stack packages. Further, through silicon via (TSV) electrodes penetrating the semiconductor chip have been proposed to realize interconnection structures that electrically connect the semiconductor chips to each other in a single stack package.

### SUMMARY

Various embodiments are directed to semiconductor devices having through via structures, methods of manufacturing the same, memory cards including the same and electronic systems including the same.

According to some embodiments, a semiconductor device includes a through electrode penetrating a substrate such that an end portion of the through electrode protrudes from a surface of the substrate, a passivation layer covering the surface of the substrate and providing a plug hole that exposes the end portion of the through electrode, and a barrier plug filling the plug hole. A top surface of the end portion of the through electrode corresponds to a bottom surface of the plug hole.

According to further embodiments, a semiconductor device includes a first through electrode penetrating a first substrate such that an end portion of the first through electrode protrudes from a surface of the first substrate, a passivation layer covering the surface of the first substrate and providing a plug hole that exposes the end portion of the first through electrode, a barrier plug filling the plug hole, a second substrate stacked on the first substrate, and a connection terminal connected to the second substrate and combined with the barrier plug. A top surface of the end portion of the first through electrode corresponds to a bottom surface of the plug hole.

According to further embodiments, a semiconductor device includes a first through electrode penetrating a first substrate such that an end portion of the first through electrode protrudes from a surface of the first substrate, a passivation layer covering the surface of the first substrate and providing a plug hole that exposes a top surface of the end portion of the first through electrode, a barrier plug filling the plug hole, a second substrate stacked on the first substrate, and a connection terminal connected to the second substrate and combined with the barrier plug. The passivation layer has a thickness which is greater than a height of the end portion of the first through electrode. The passivation layer includes an insulation layer that covers the surface of the first substrate and extends onto sidewalls of the end portion of the first through electrode and sidewalls of the barrier plug.

According to further embodiments, a method of manufacturing a semiconductor device includes forming a through electrode penetrating a substrate such that an end portion of the through electrode protrudes from a surface of the substrate, forming a passivation layer that covers the surface of the substrate and provides a plug hole exposing the end portion of the through electrode, and forming a barrier plug filling the plug hole. A top surface of the end portion of the through electrode corresponds to a bottom surface of the plug hole.

According to further embodiments, a memory card includes a semiconductor device. The semiconductor device includes a through electrode penetrating a substrate such that an end portion of the through electrode protrudes from a surface of the substrate, a passivation layer covering the surface of the substrate and providing a plug hole that exposes the end portion of the through electrode, and a barrier plug filling the plug hole. A top surface of the end portion of the through electrode corresponds to a bottom surface of the plug hole.

According to further embodiments, a memory card includes a semiconductor device. The semiconductor device includes a first through electrode penetrating a first substrate such that an end portion of the first through electrode protrudes from a surface of the first substrate, a passivation layer covering the surface of the first substrate and providing a plug hole that exposes the end portion of the first through electrode, a barrier plug filling the plug hole, a second substrate stacked on the first substrate, and a connection terminal connected to the second substrate and combined with the barrier plug. A top surface of the end portion of the first through electrode corresponds to a bottom surface of the plug hole.

According to further embodiments, a memory card includes a semiconductor device. The semiconductor device includes a first through electrode penetrating a first substrate such that an end portion of the first through electrode protrudes from a surface of the first substrate, a passivation layer covering the surface of the first substrate and providing a plug hole that exposes a top surface of the end portion of the first through electrode, a barrier plug filling the plug hole, a second substrate stacked on the first substrate, and a connection terminal connected to the second substrate and combined with the barrier plug. The passivation layer has a thickness which is greater than a height of the end portion of the first through electrode. The passivation layer includes an insulation layer that covers the surface of the first substrate and extends onto sidewalls of the end portion of the first through electrode and sidewalls of the barrier plug.

According to further embodiments, an electronic system includes a semiconductor device. The semiconductor device includes a through electrode penetrating a substrate such that an end portion of the through electrode protrudes from a surface of the substrate, a passivation layer covering the surface of the substrate and providing a plug hole that exposes the end portion of the through electrode, and a barrier plug filling the plug hole. A top surface of the end portion of the through electrode corresponds to a bottom surface of the plug hole.

According to further embodiments, an electronic system includes a semiconductor device. The semiconductor device includes a first through electrode penetrating a first substrate such that an end portion of the first through electrode protrudes from a surface of the first substrate, a passivation layer covering the surface of the first substrate and providing a plug hole that exposes the end portion of the first through electrode, a barrier plug filling the plug hole, a second substrate stacked on the first substrate, and a connection terminal connected to the second substrate and combined with the barrier plug. A top surface of the end portion of the first through electrode corresponds to a bottom surface of the plug hole.

According to further embodiments, an electronic system includes a semiconductor device. The semiconductor device includes a first through electrode penetrating a first substrate such that an end portion of the first through electrode protrudes from a surface of the first substrate, a passivation layer covering the surface of the first substrate and providing a plug hole that exposes a top surface of the end portion of the first through electrode, a barrier plug filling the plug hole, a second substrate stacked on the first substrate, and a connection terminal connected to the second substrate and combined with the barrier plug. The passivation layer has a thickness which is greater than a height of the end portion of the first through electrode. The passivation layer includes an insulation layer that covers the surface of the first substrate and extends onto sidewalls of the end portion of the first through electrode and sidewalls of the barrier plug.

### BRIEF DESCRIPTION OF THE DRAWINGS

Embodiments of the present invention will become more apparent in view of the attached drawings and accompanying detailed description, in which:

FIG. 1 is a cross-sectional view illustrating a semiconductor device according to some embodiments of the present invention;

FIG. 2 is an enlarged cross-sectional view illustrating a portion “11” of FIG. 1;

FIG. 3 is an enlarged cross-sectional view illustrating an interconnection structure between semiconductor devices according to some embodiments of the present invention;

FIG. 4 is a cross-sectional view illustrating a stacked structure of a semiconductor device according to some embodiments of the present invention;

FIGS. 5 to 11 are cross-sectional views illustrating a method of manufacturing a semiconductor device according to some embodiments of the present invention;

FIG. 12 is a cross-sectional view illustrating a through electrode of a semiconductor device according to some embodiments of the present invention;

FIG. 13 is a block diagram illustrating an example of an electronic system employing a memory card including a semiconductor device in accordance with an embodiment; and

FIG. 14 is a block diagram illustrating an example of an electronic system including a semiconductor device in accordance with an embodiment.

### DETAILED DESCRIPTION OF THE EMBODIMENTS

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concept.

It will also be understood that when an element is referred to as being “on,” “above,” “below,” or “under” another element, it can be directly “on,” “above,” “below,” or “under” the other element, respectively, or intervening elements may also be present.

Accordingly, the terms such as “on,” “above,” “below,” or “under” which are used herein are for the purpose of describing particular embodiments only and are not intended to limit the scope of this disclosure.

It will be further understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion. The semiconductor substrate may have an active layer corresponding to a region where transistors and internal interconnection lines constituting electronic circuits are integrated, and the semiconductor chips may be obtained by separating the semiconductor substrate having a wafer into a plurality of pieces using a die sawing process.

The semiconductor chips may correspond to memory chips or logic chips. The memory chips may include dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits or phase change random access memory (PcRAM) circuits which are integrated on and/or in the semiconductor substrate. The logic chip may include logic circuits which are integrated with the semiconductor substrate. In some cases, the term “semiconductor substrate” used herein may be construed as a semiconductor chip or a semiconductor die in which integrated circuits are formed.

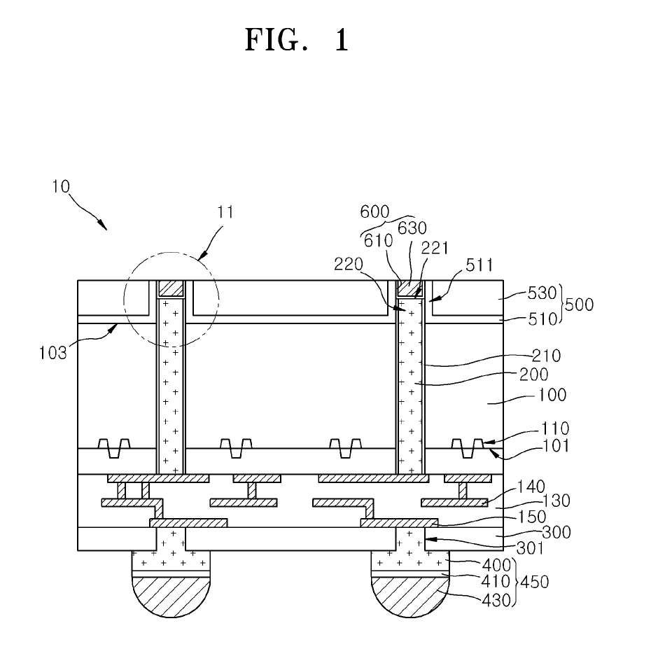

Referring to FIG. 1, a semiconductor device 10 may include a semiconductor substrate 100 and through electrodes 200 vertically penetrating the semiconductor substrate 100. Backside end portions 220 of the through electrodes 200 may extend to protrude from a first surface 103 of the semiconductor substrate 100. The through electrodes 200 may correspond to through silicon vias (TSVs). That is, each of the through electrodes 200 may be a conductive via that extends from a second surface 101 of the semiconductor substrate 100 toward the first surface 103 of the semiconductor substrate 100. The second surface 101 may correspond to a front side surface of the semiconductor substrate 100 and the first surface 103 may correspond to a back side surface of the semiconductor substrate 100. The semiconductor substrate 100 may be composed of a semiconductor material such as a silicon material. The semiconductor substrate 100 may be a wafer or an individual chip which is separated from the wafer.

The second surface 101 of the semiconductor substrate 100 may be a surface which is adjacent to the active layer where integrated circuits are formed, and the first surface 103 may be an opposite surface to the second surface 101. Circuit elements such as transistors 110 constituting the integrated circuits may be formed in and/or on the active layer, and an interlayer insulation layer 130 and an internal interconnection structure 140 may be disposed on the second surface 101. The internal interconnection structure 140 may have a multi-layered structure. The transistors 110 may be formed to act as cell transistors for memory cells in an embodiment in which the semiconductor device 10 is a memory device or to act as circuit elements constituting logic circuits in an embodiment in which the semiconductor device 10 is a non-memory device such as a logic device.

The internal interconnection structure 140 may include interconnection lines and connection vias to provide an electrical connection structure. The internal interconnection structure 140 may be electrically connected to connection pads 150 disposed in or on the interlayer insulation layer 130, and conductive bumps 400 acting as external connection terminals may be disposed on respective connection pads 150. In other words, in an embodiment, conductive bumps 400 are an element of a connection terminal 450 which connects staked substrates. Other components of a connection terminal 450 may include interfacial layer 410 and conductive adhesion layer 430. In other embodiments, other configurations of connection terminals are possible.

The conductive bumps 400 may correspond to front bumps electrically connected to the through electrodes 200. A first passivation layer 300 corresponding to an insulation layer may be disposed on a surface of the interlayer insulation layer 130 opposite to the semiconductor substrate 100. The first passivation layer 300 may include a plurality of holes 301 that expose the connection pads 150, and the conductive bumps 400 may be connected to the connection pads 150 through the holes 301.

The through electrodes 200 may be electrically connected to the conductive bumps 400 through the internal interconnection structure 140, as illustrated in FIG. 1. However, embodiments are not limited thereto. In some embodiments, the through electrodes 200 may be directly connected to the conductive bumps 400, or each through electrode 200 and corresponding bump 400 may constitute a single unified body without any heterogeneous junction therebetween. The conductive bumps 400 may include a metal material such as a copper material or an alloy material containing copper.

Conductive adhesion layers 430 may be disposed on respective conductive bumps 400 to improve the contact reliability between the conductive bumps 400 and external terminals. The conductive adhesion layers 430 may be formed to include a solder layer containing a tin (Sn) material. An interfacial layer 410 may be additionally disposed between the conductive adhesion layers 430 and the conductive bumps 400. The interfacial layer 410 may act as a wetting layer or a barrier layer suppressing contamination or oxidation of the conductive bumps 400. The interfacial layer 410 may contain a nickel material, a gold material, or a combination thereof.

The through electrodes 200 may be fabricated using a process technology for forming TSVs. The through electrodes 200 may be formed of a copper material or an alloy material containing copper. In some embodiments, the through electrodes 200 may be formed to include gallium (Ga), indium (In), tin (Sn), silver (Ag), mercury (Hg), bismuth (Bi), lead (Pb), gold (Au), Zinc (Zn), aluminum (Al), or an alloy containing at least one of these materials. Each of the through electrodes 200 may penetrate the semiconductor substrate 100 to have a through via shape, and the backside end portions 220 of the through electrodes 200 may protrude from the first surface 103 of the semiconductor substrate 100. An electrode insulation layer 210 may surround sidewalls of the through electrodes 200 to electrically insulate the through electrodes 200 from the semiconductor substrate 100. The electrode insulation layer 210 may prevent copper ions in the through electrodes 200 from diffusing or migrating into the semiconductor substrate 100.

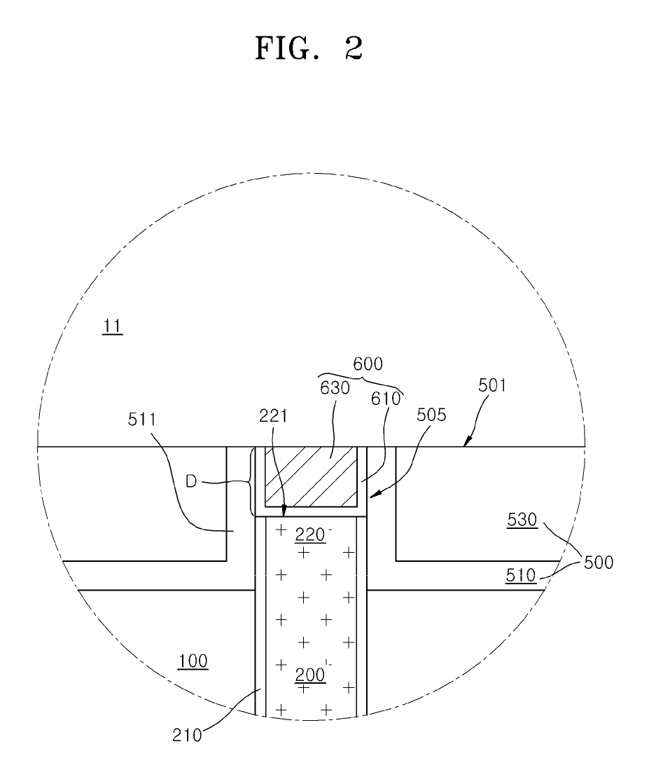

Referring to FIGS. 1 and 2, the backside end portions 220 of the through electrodes 200 may protrude from the first surface 103 of the semiconductor substrate 100 to be inserted into a second passivation layer 500 covering the first surface 103 of the semiconductor substrate 100. As illustrated in FIG. 2 corresponding to an enlarged view of portion “11” of FIG. 1, a top surface 221 of the backside end portion 220 of each through electrode 200 may be lower than a top surface 501 of the second passivation layer 500. A level difference D between the top surface 221 of the backside end portion 220 and the top surface 501 of the second passivation layer 500 may be consistent with a vertical thickness of a barrier plug 600 disposed on the top surface 221 of the backside end portion 220.

The barrier plugs 600 may penetrate the second passivation layer 500 to be in contact with the backside end portions 220 of the through electrodes 200. The barrier plugs 600 may fill plug holes 505 that penetrate the second passivation layer 500 to expose the backside end portion 220 of the through electrodes 200. That is, the barrier plugs 600 may be formed to cover the top surfaces 221 of the backside end portions 220 of the through electrodes 200. As a result, the backside end portions 220 of the through electrodes 200 may be enclosed by the barrier plugs 600. Top surfaces of the barrier plugs 600 may be substantially coplanar with the top surface 501 of the second passivation layer 500. The second passivation layer 500 may surround sidewalls of the barrier plugs 600 and to expose the top surfaces of the barrier plugs 600. Thus, the top surfaces of the barrier plugs 600 may be used as contact surfaces when the barrier plugs 600 are electrically connected to an external device. Accordingly, the backside end portions 220 of the through electrodes 200 may be physically protected due to the presence of the barrier plugs 600 when a process of electrically connecting the semiconductor device to an external device is performed.

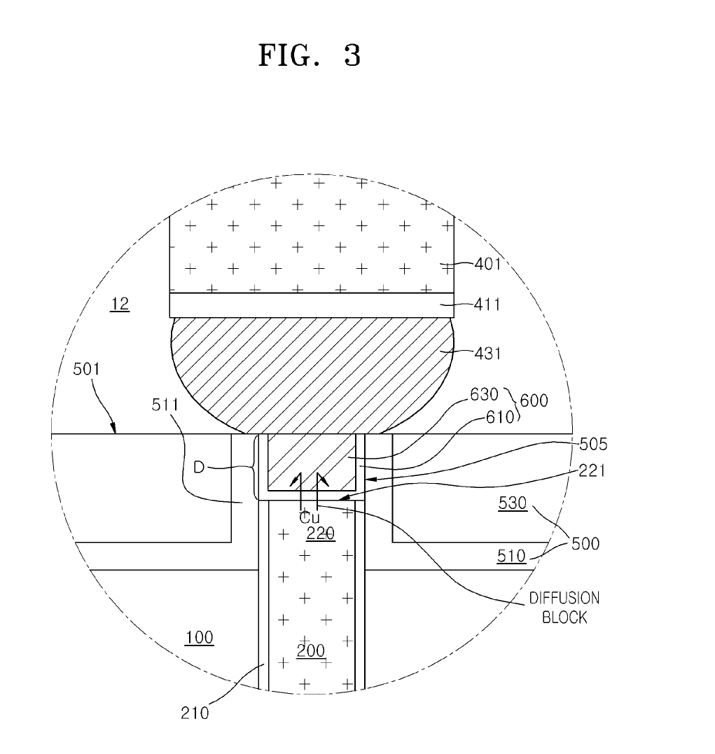

Referring to FIGS. 2 and 3, when the semiconductor device 10 is electrically connected to another semiconductor device, a conductive bump 401 of the other semiconductor device may be electrically connected to the barrier plug 600 of the semiconductor device 10 through a solder layer acting as a conductive adhesion layer 431. An interfacial layer 411 may be disposed between the conductive bump 401 and the conductive adhesion layer 431. That is, when another substrate is stacked on the semiconductor substrate 100, the other substrate may be electrically and mechanically combined with the semiconductor substrate 100 using a soldering process that is performed through a pressurizing step and a heating step (or an ultrasonic step). As a result, an interconnection structure 12 for electrically connecting the semiconductor device 10 to the other semiconductor device may be realized, as illustrated in FIG. 3.

While the semiconductor device 10 is combined with the other semiconductor device, copper atoms or copper ions contained in the through electrodes 200 (i.e., the backside end portions 220 of the through electrodes 200) may be excited or activated to have sufficient energy to be diffused out of the through electrodes 200. However, according to embodiments, the top surfaces 221 of the backside end portions 220 of the through electrodes 200 may be covered with the barrier plugs 600 and the sidewalls of the backside end portions 220 of the through electrodes 200 may be surrounded by the second passivation layer 500. Thus, the barrier plugs 600 and the second passivation layer 500 may prevent the copper atoms or the copper ions contained in the backside end portions 220 of the through electrodes 200 from being diffused out after the soldering process is performed to combine the semiconductor device 10 with the other semiconductor device. That is, even though the copper atoms or the copper ions in the backside end portions 220 of the through electrodes 200 are sufficiently excited to have diffusible energy, the barrier plugs 600 blocks the migration or diffusion of the copper atoms or the copper ions.

Further, the barrier plugs 600 may prevent tin (Sn) atoms in the conductive adhesion layer 431 from being diffused into the through electrodes 200. Thus, the barrier plugs 600 may prevent a chemical reaction between the tin (Sn) atoms in the conductive adhesion layer 431 and the copper (Cu) atoms in the through electrodes 200 from occurring formation of an inter-metallic compound material. That is, when the through electrodes 200 are electrically connected to the conductive bumps 401 of the other semiconductor device to realize the interconnection structure 12, the barrier plugs 600 may suppress formation of an inter-metallic compound material that degrades the reliability of the interconnection structure 12. As a result, the presence of the barrier plugs 600 may improve the reliability of the interconnection structure 12.

In an embodiment, only the top surfaces of the barrier plugs 600 may be exposed the second passivation layer 500. The barrier plugs 600 may be vertically aligned with respective backside end portions 220 of the through electrodes 200. That is, barrier plug 600 may be coaxial with backside end portion 220. In addition, a diameter of each barrier plug 600 may be substantially equal to a diameter of each backside end portion 220. As a result, since the barrier plugs 600 can be formed to have substantially the same pitch size as the backside end portions 220 of the through electrodes 200, the interconnection structure 12 may also be realized to have a fine pitch size. The interconnection structure 12 may be realized even without use of any backside bumps that are disposed on respective barrier bumps 600 that have a size greater than the backside end portions 220. Hence, the interconnection structure 12 may be applied to wafer level packages (WLPs) that require a fine pitch size.

Referring again to FIG. 2, the barrier plug 600 may be formed to include a conductive material which is capable of blocking the diffusion of copper atoms. The barrier plug 600 may be formed to include a first metal layer 610 and a second metal layer 630 which are different from each other. The first metal layer 610 may be disposed between the backside end portion 220 and the second metal layer 630. In addition, the first metal layer 610 may extend to cover sidewalls of the second metal layer 630. As a result, the first metal layer 610 may cover a bottom surface and sidewalls of the second metal layer 630.

The second metal layer 630 may be formed on the first metal layer 610 using a plating process. The first metal layer 610 may include a seed layer used in a plating process or a barrier metal layer. Alternatively, the first metal layer 610 may have a multi-layered structure including a seed layer and a barrier metal layer disposed under the seed layer. In some embodiments, the first metal layer 610 may be formed of a titanium (Ti) layer or an alloy layer containing titanium (Ti). In some embodiments, the first metal layer 610 may be formed to include a titanium (Ti) layer and a copper (Cu) layer deposited on the titanium (Ti) layer. In an embodiment in which no copper backside bumps are disposed on the through electrodes 200, a copper plating process for forming the copper backside bumps may not be performed. In such an embodiment, a process for forming a copper (Cu) layer constituting the first metal layer 610 may be omitted.

The second metal layer 630 may include a metal material which is capable of blocking the diffusion of tin (Sn) atoms contained in the conductive adhesion layer 431 from being diffused into the through electrodes 200. For example, the second metal layer 630 may include at least one of a nickel (Ni) material, a palladium (Pd) material, a cobalt (Co) material, a chrome (Cr) material and a rhodium (Rh) material.

The second metal layer 630 may include a nickel (Ni) layer to provide a diffusion barrier layer preventing diffusion of tin atoms or tin ions. The nickel (Ni) layer of the second metal layer 630 may act as a wetting layer to provide a reliable combination of the conductive adhesion layer (431 of FIG. 3) and the barrier plug 600 of the interconnection structure 12 shown in FIG. 3. The barrier plug 600 may further include a gold (Au) layer deposited on the nickel (Ni) layer. In such case in embodiment, the gold (Au) layer may act as an oxidation resistant layer. The barrier plug 600 may fill the plug hole 505 to have a thickness for sufficient to prevent the diffusion of tin and copper atoms or ions.

The first metal layer 610 may cover the top surface 221 of the through electrode 200 exposed by the plug hole 505 and may extend to cover sidewalls of the second passivation layer 500 exposed by the plug hole 505. Thus, the first metal layer 610 may have a concave shape with a “U” shaped cross section having a space in the middle. The second metal layer 630 may fill the space in the middle of the first metal layer 610 having a concave shape.

Referring again to FIGS. 1 and 2, the second passivation layer 500 may cover the first surface 103 (i.e., a backside surface) of the semiconductor substrate 100. The second passivation layer 500 may have a thickness which is greater than a height of the backside end portion 220 that protrudes from the first surface 103 of the semiconductor substrate 100. The second passivation layer 500 may include an organic material such as a polymer material. For example, the second passivation layer 500 may include a polyimide material. Alternatively, the second passivation layer 500 may include an inorganic material such as a silicon oxide (SiO₂) layer, a silicon nitride (Si₃N₄) layer or a silicon oxynitride (SiON) layer.

The second passivation layer 500 may have a multi-layered structure including a plurality of dielectric layers that have different dielectric constants. For example, the second passivation layer 500 may include a first insulation layer 510 and a second insulation layer 530. The first insulation layer 510 may cover the first surface 103 of the semiconductor substrate 100 and may extend onto sidewalls of the backside end portion 220 and the barrier plug 600. In such casein embodiment, the portion of the first insulation layer 510 surrounding the sidewalls of the backside end portion 220 and the barrier plug 600 may correspond to a protective ring portion 511.

The second insulation layer 530 may be disposed on the first insulation layer 510. The first insulation layer 510 may be a conformal liner layer. The second insulation layer 530 may be deposited on the first insulation layer 510 and may fill a space between portions of the first insulation layer 510 disposed over sidewalls of the barrier plug 600 and the backside end portion 220. In addition, second insulation layer 530 may act as a buffer layer providing a flat surface across the top of the second passivation layer 500. That is, the second insulation layer 530 may provide a flatness of the top surface 501 of the second passivation layer 500 and may alleviate a stress applied to the second passivation layer 500. Accordingly, even when a stress is applied to the second passivation layer 500 during formation of the interconnection structure (12 of FIG. 3), the second insulation layer 530 may prevent the mechanical reliability of the interconnection structure 12 from being degraded. The second insulation layer 530 may include a silicon oxide (SiO₂) layer. The first insulation layer 510 may act as a diffusion barrier layer that blocks lateral diffusion or lateral migration of the copper ions contained in the backside end portion 220 of the through electrode 200. The first insulation layer 510 may include a silicon nitride (Si₃N₄) layer or a silicon oxynitride (SiON) layer to effectively block the diffusion or migration of metal ions. If the copper ions contained in the through electrode 200 are diffused onto the first surface 103 of the semiconductor substrate 100, the copper ions may chemically react with silicon atoms contained in the semiconductor substrate 100 to generate a copper-silicon compound material. In addition, if the copper ions contained in the through electrode 200 are diffused into the semiconductor substrate 100, the copper ions may degrade characteristics of circuit elements (e.g., transistors) of integrated circuits formed in the semiconductor substrate 100. For example, the copper ions may degrade a threshold voltage characteristic or a leakage current characteristic of the transistors to cause a poor refresh characteristic or a poor standby current characteristic of a memory device. However, according to embodiments, the insulation layer 210 and the first insulation layer 510 may prevent the copper ions contained in the through electrode 200 from being diffused into the semiconductor substrate 100. Accordingly, the insulation layer 210 and the first insulation layer 510 may reduce copper contamination of the semiconductor substrate 100.

The second passivation layer 500 may further include a diffusion barrier layer or a stress buffer layer disposed on the first and second insulation layers 510 and 530. In an embodiment, the diffusion barrier layer may include a silicon nitride (Si₃N₄) layer or a silicon oxynitride (SiON) layer, and the stress buffer layer may include a silicon oxide (SiO₂) layer. In some embodiments, the second passivation layer 500 may be formed of only the first insulation layer 510 without the second insulation layer 530 such that the protective ring portion 511 of the first insulation layer 510 has a protruded shape when the interconnection structure 12 is realized. In such a case, the first insulation layer 510 may be conformally formed of a combination layer including a silicon nitride layer (or a silicon oxynitride layer) and a silicon oxide layer which are sequentially deposited.

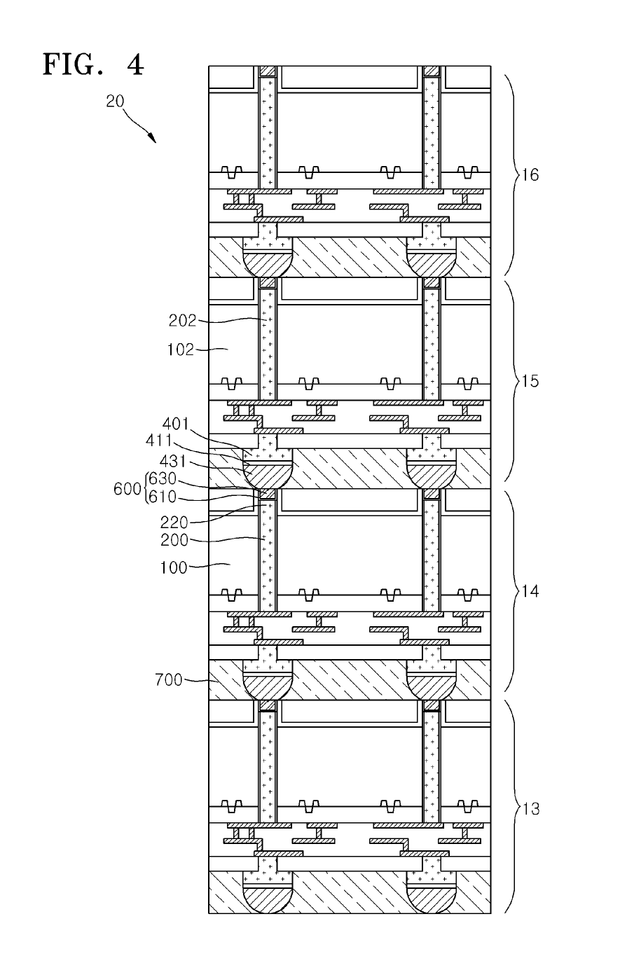

Referring to FIGS. 1 and 4, a semiconductor device 20 according to some embodiments may be realized in the form of a stack package including a plurality of chips which are sequentially stacked. In such an embodiment, each of the plurality of chips may correspond to the semiconductor device 10 illustrated in FIG. 1. That is, the semiconductor device 20 may include a plurality of semiconductor chips 13, 14, 15 and 16 which are sequentially stacked, and each of the semiconductor chips 13, 14, 15 and 16 may have substantially the same configuration as the semiconductor device 10 described with reference to FIG. 1. In some embodiments, the topmost semiconductor chip 16 may not include the through electrodes 200, the barrier plugs 600 and the second passivation layer 500.

A first semiconductor chip, for example, the second bottommost semiconductor chip 14 among the stacked semiconductor chips 13, 14, 15 and 16 may include a first semiconductor substrate 100, first through electrodes 200 penetrating the first semiconductor substrate 100 and barrier plugs 600 enclosing backside end portions 220 of the first through electrodes 200, as described with reference to FIG. 1. A second semiconductor chip, for example, the second topmost semiconductor chip 15 stacked on the first semiconductor chip 14 may include a second semiconductor substrate 102, second through electrodes 202 penetrating the second semiconductor substrate 200 and conductive bumps 401 electrically connected to the second through electrodes 202, as described with reference to FIGS. 1 and 3.

The conductive bump 401 of the second semiconductor chip 15 and the backside end portion 220 of the first through electrode 200 of the first semiconductor chip 14 may constitute the interconnection structure (12 of FIG. 3), as described with reference to FIG. 3, to provide a mechanical and electrical interconnection structure between first and second semiconductor chips 14 and 15. For example, the conductive adhesion layer 431 corresponding to a solder layer may be combined with the barrier plug 600 to electrically and physically connect the first semiconductor chip 14 to the second semiconductor chip 15. Adhesive insulation layers 700 may be disposed between the semiconductor chips 13, 14, 15 and 16 to bond the semiconductor chips 13, 14, 15 and 16 to each other.

Although not shown in the drawings, in an embodiment, the semiconductor chips 13, 14, 15 and 16 may be mounted and stacked on a printed circuit board (PCB) or an interposer. Alternatively, the semiconductor chips 13, 14, 15 and 16 may be embedded in a substrate. In addition, the semiconductor chips 13, 14, 15 and 16 may be covered and encapsulated by an epoxy molding compound (EMC) material (not shown).

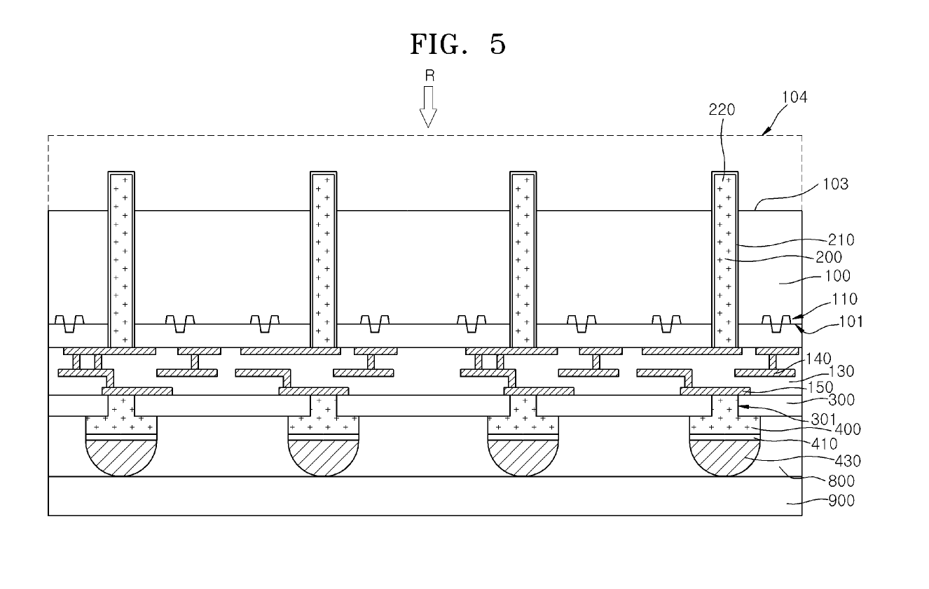

Referring to FIG. 5, through electrodes 200 may extend from a second surface 101 (corresponding to a front side surface) of a semiconductor substrate 100 toward a third surface 104 (corresponding to an initial backside surface) of the semiconductor substrate 100. The through electrodes 200 may be formed using a process for forming through silicon vias (TSVs) at a wafer level. An insulation layer 210 may be formed between the through electrodes 200 and the semiconductor substrate 100 to electrically insulate the through electrodes 200 from the semiconductor substrate 100.

A recess process R may be applied to the third surface 104 of the semiconductor substrate 100 to form a first surface 103 exposing backside end portions 220 of the through electrodes 200. In more detail, the semiconductor substrate 100 may be attached to a carrier substrate 900 using an adhesive agent 800, and a predetermined thickness of a backside portion of the semiconductor substrate 100 may be removed. The backside portion of the semiconductor substrate 100 may be removed using at least one of a dry etch process, a wet etch process and a back grinding process. In some embodiments, extra second etch process may be additionally performed such that all of the backside end portions 220 of the through electrodes 200 protrude from the first surface 103 of the semiconductor substrate 100.

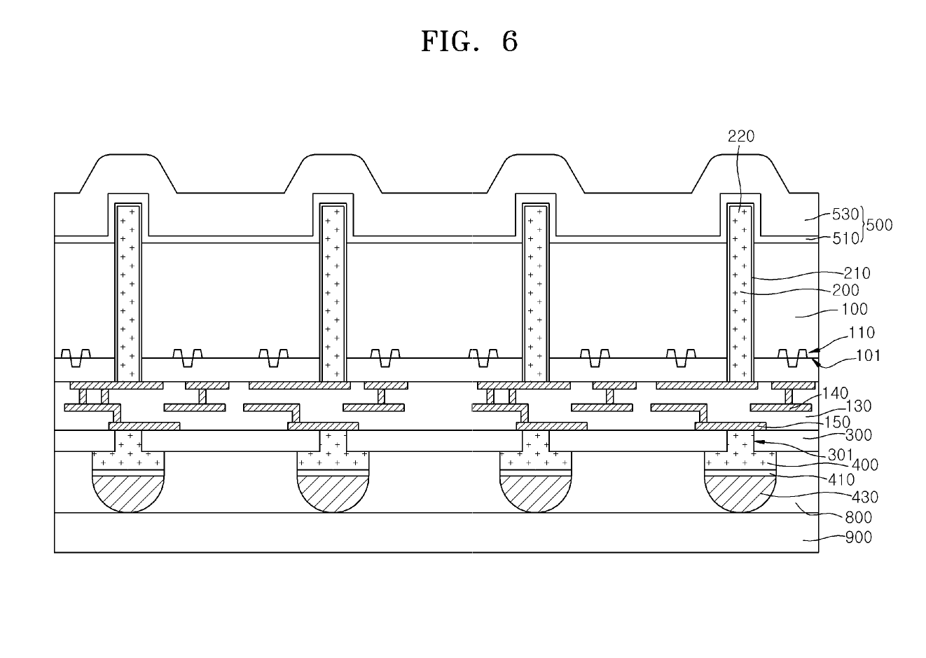

Referring to FIG. 6, a second passivation layer 500 may be formed on the first surface 103 of the semiconductor substrate 100 to cover the backside end portions 220 of the through electrodes 200. The second passivation layer 500 may be formed to include a first insulation layer 510 and a second insulation layer 530. The second passivation layer 500 may be formed to include an organic material layer or an inorganic material layer.

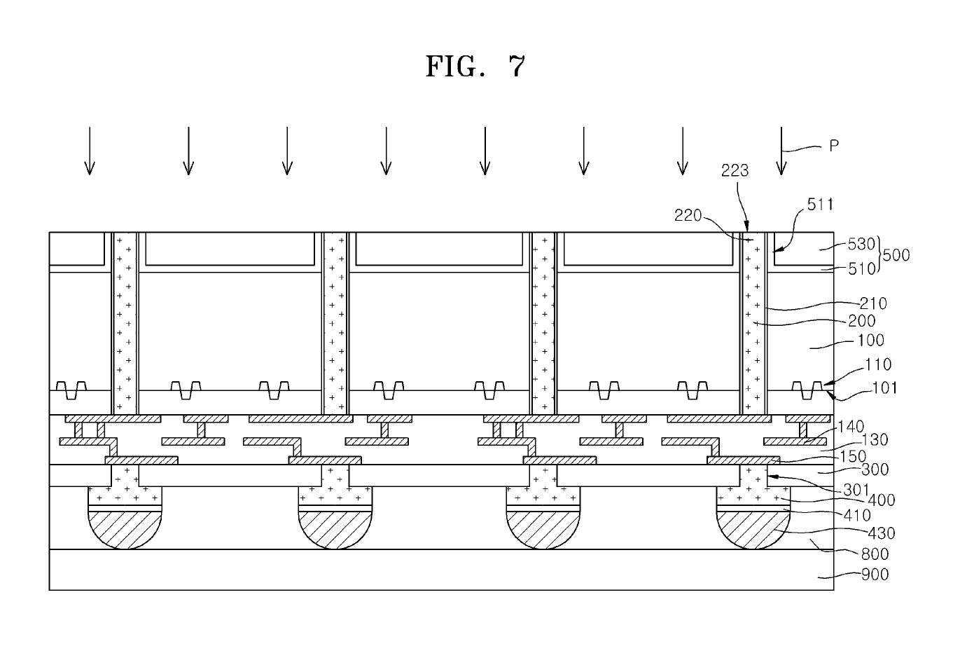

Referring to FIG. 7, a planarization process P may be applied to the second passivation layer 500 to expose initial top surfaces 223 of the backside end portions 220 of the through electrodes 200. In an embodiment in which the second passivation layer 500 is formed to include an organic material layer such as a polymer layer, the initial top surfaces 223 of the backside end portions 220 may be exposed by removing a portion of the second passivation layer 500 on the backside end portions 220 of the through electrodes 200 using a surface treatment process or a dry etch process. Alternatively, when the second passivation layer 500 is formed to include an inorganic material layer, the initial top surfaces 223 of the backside end portions 220 may be exposed by planarizing the second passivation layer 500 using a planarization process such as a chemical mechanical polishing (CMP) process.

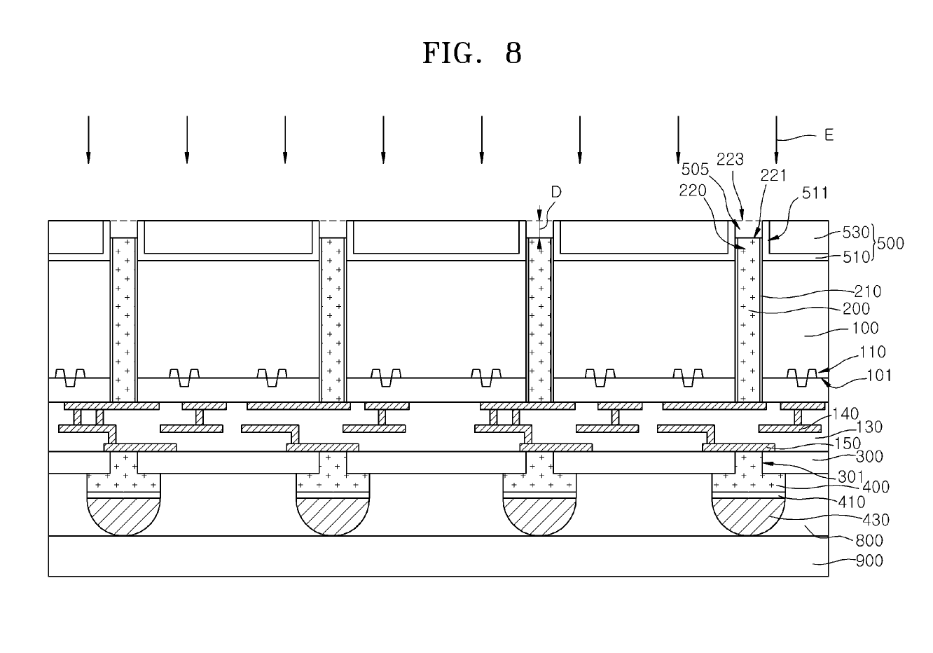

Referring to FIG. 8, an etch process E may be selectively applied to the initial top surfaces 223 of the backside end portions 220 to form recessed surfaces 221 of the backside end portions 220. As a result, plug holes 505 surrounded by the second passivation layer 500 may be formed on respective backside end portions 220. The plug holes 505 may be formed by selectively etching the backside end portions 220. Thus, the plug holes 505 may be aligned with the remaining backside end portions 220 of the through electrodes 200, and each of the plug holes 505 may have substantially the same diameter as the backside end portion 220 thereunder. If the through electrodes 200 are formed of a copper material, the etch process E may be performed using a wet etch process for removing a copper material.

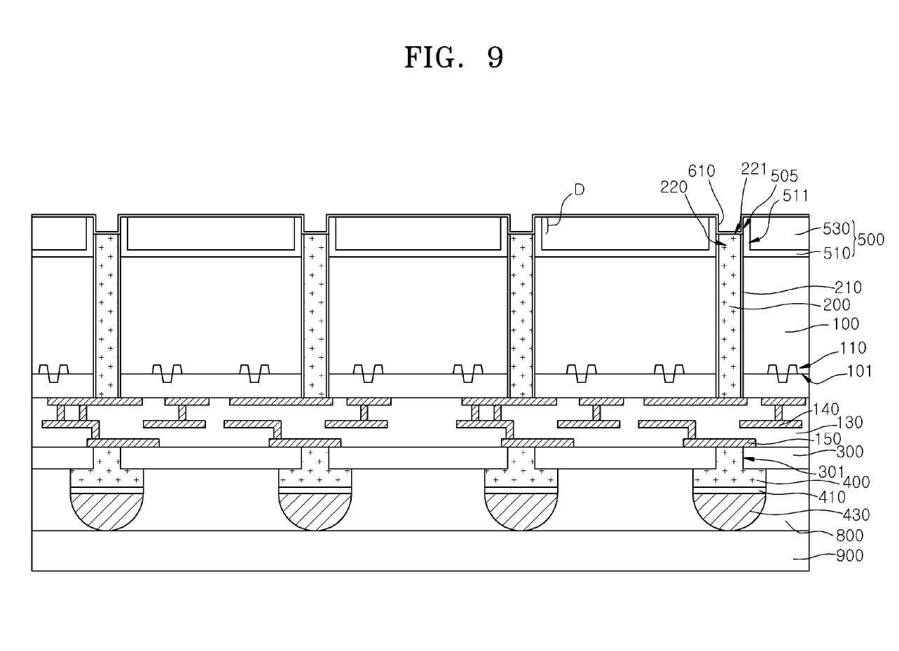

Referring to FIG. 9, a first metal layer 610 acting as a seed layer may be conformally formed to cover the recessed surfaces 221 of the backside end portions 220 and to extend onto a surface of the second passivation layer 500.

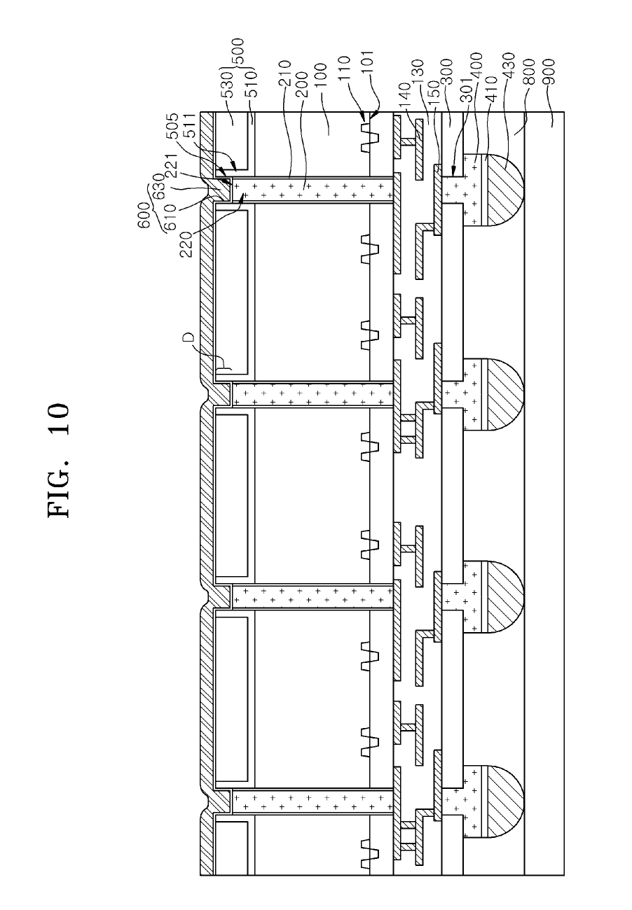

Referring to FIG. 10, a second metal layer 630 may be formed on the first metal layer 610 to fill the plug holes 505. The first and second metal layers 610 and 630 may constitute a layer for barrier plugs 600.

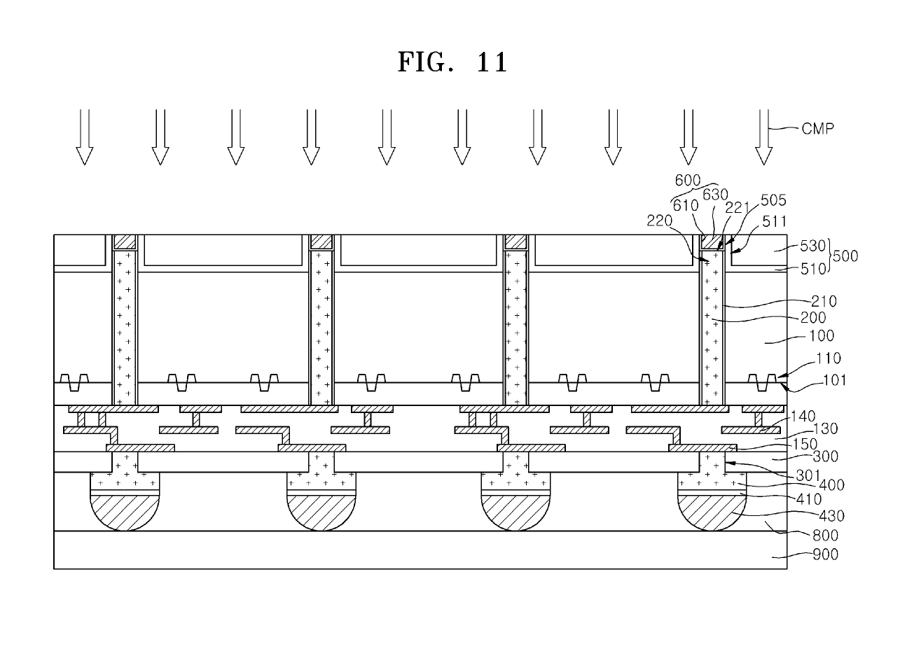

Referring to FIG. 11, the layer for barrier plugs 600 may be planarized to expose a top surface of the second passivation layer 500 and to form the barrier plugs 600 in respective plug holes 505. The layer for barrier plugs 600 may be planarized using a chemical mechanical polishing (CMP) process.

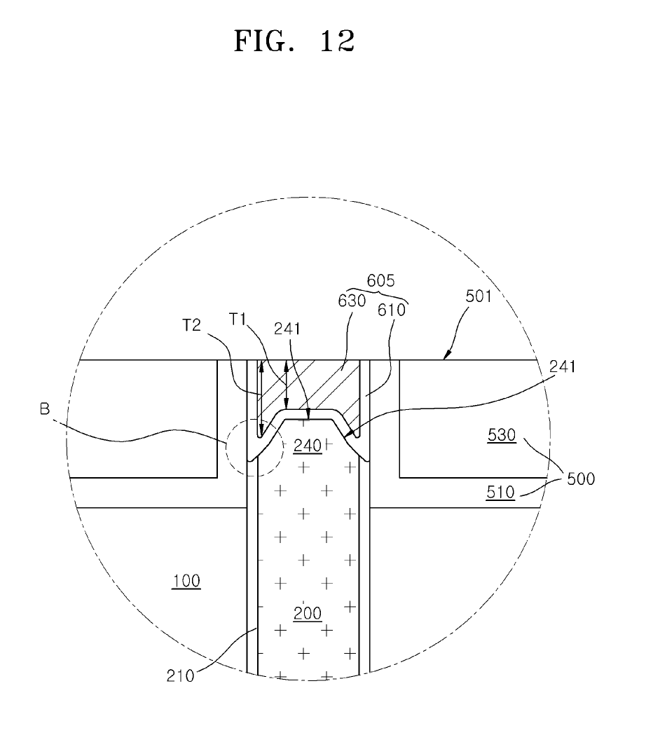

FIG. 12 is a cross-sectional view illustrating a through electrode of a semiconductor device according to some embodiments of the present invention.

Referring to FIG. 12, a backside end portion 240 of a through electrode 200 may have a cone-shaped configuration or a convex surface. This backside end portion 240 of the through electrode 200 may be formed by appropriately changing an etch recipe of the etch process E described with reference to FIG. 8 to increase an etch rate in an interface region B between the second passivation layer 500 and the through electrode 200 relative to an etch rate of a center portion. That is, when the backside end portion 240 of the through electrode 200 is recessed, the etch recipe of etch process E may be appropriately changed such that the etch rate in the interface region B is higher than an etch rate in a central region of the backside end portion 240 of the through electrode 200. As a result, the central region of the backside end portion 240 may be less recessed than an edge region of the backside end portion 240. Thus, the backside end portion 240 may be recessed to have a cone-shaped configuration or a convex surface, as described above.

The backside end portion 240 having a cone-shaped configuration or a convex surface may be enclosed by a barrier plug 605 that fills a plug hole surrounded by the second passivation layer 500. The barrier plug 605 may have a bottom surface profile which is consistent with a topology of a top surface 241 of the backside end portion 240. For example, since a central thickness T1 of the second metal layer 630 of the barrier plug 605 is less than an edge thickness T2 of the second metal layer 630, the barrier plug 605 may have a concave bottom surface. If the edge thickness T2 of the second metal layer 630 is greater than the central thickness T1 of the second metal layer 630, the barrier plug 605 may more effectively prevent copper ions in the through electrode 200 from being diffused out. This is because metal ions such as the copper ions are more readily diffused or migrated along an interface between two different material layers. However, according to some embodiments, the edge thickness T2 of a portion of the second metal layer 630 adjacent to the interface region B may be greater than the central thickness T1 of the second metal layer 630. Thus, the barrier plug 605 may effectively block the out-diffusion of the copper ions contained in the through electrode 200.

According to embodiments, reliable interconnection structures for electrically connecting through electrodes of a semiconductor device to an external device and a method of manufacturing the reliable interconnection structures may be provided. The number of processes applied to a backside surface of a semiconductor substrate may also be reduced by forming the through electrodes at a wafer level. Thus, fabrication cost of the semiconductor device may be reduced. Further, backside end portions of the through electrodes constituting the reliable interconnection structures may be electrically connected to an external device without use of any backside bumps. Thus, the reliable interconnection structures may be realized to have a fine pitch size of about 20 micrometers to about 30 micrometers.

Moreover, the reliable interconnection structures may be realized to have barrier plugs that prevent copper ions in the through electrodes from being diffused out. In addition, the barrier plugs may prevent a chemical reaction between external terminals of the external device and copper ions in the through electrodes to reduce formation of an inter-metallic compound material. As a result, the electrical and mechanical reliability of the interconnection structures may be improved.

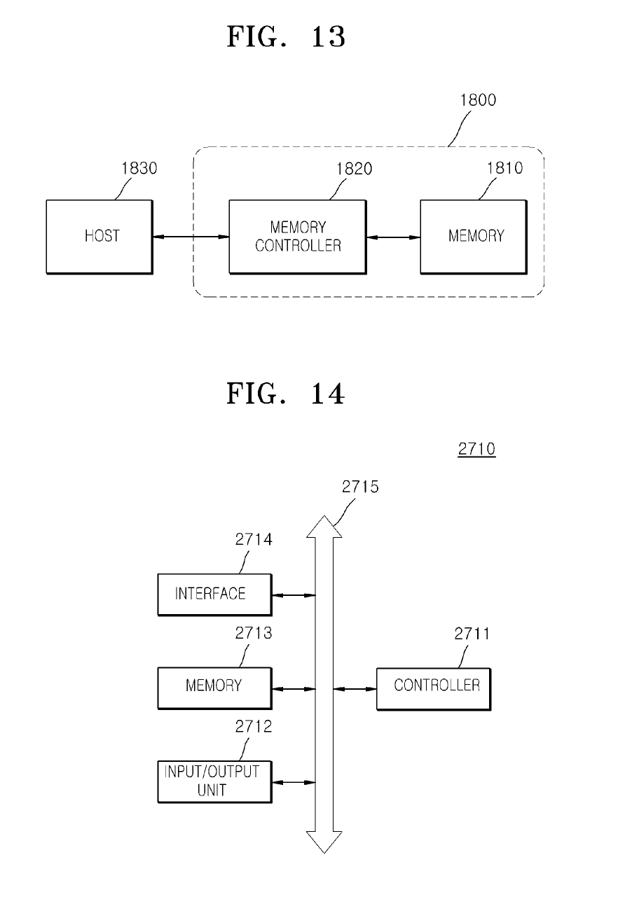

Referring to FIG. 13, a semiconductor device in accordance with embodiments of this disclosure may be provided in the form of a memory card 1800. For example, the memory card 1800 may include a memory 1810 such as a nonvolatile memory device and a memory controller 1820. The memory 1810 and the memory controller 1820 may store data or read stored data.

The memory 1810 may include at least one nonvolatile memory device to which the technology of embodiments of the present invention is applied. The memory controller 1820 may control the memory 1810 such that stored data is read out or data is stored in response to a read/write request from a host 1830.

Referring to FIG. 14, a semiconductor device in accordance with an embodiment may be applied to an electronic system 2710. An electronic system 2710 may include a controller 2711, an input/output unit 2712, and a memory 2713. The controller 2711, the input/output unit 2712 and the memory 2713 may be coupled with one another through a bus 2715 providing a path through which data moves.

For example, the controller 2711 may include at least one microprocessor, at least one digital signal processor, at least one microcontroller, or logic devices capable of performing the same functions as these components. The controller 2711 or the memory 2713 may include at least one semiconductor device according to embodiments of the present invention. The input/output unit 2712 may include at least one selected among a keypad, a keyboard, a display device, a touchscreen and so forth. The memory 2713 is a device for storing data. The memory 2713 may store data and/or commands to be executed by the controller 2711, and the like.

The memory 2713 may include a volatile memory device such as a DRAM and/or a nonvolatile memory device such as a flash memory. For example, a flash memory may be mounted to an information processing system such as a mobile terminal or a desk top computer. The flash memory may constitute a solid state disk (SSD). In this case, the electronic system 2710 may stably store a large amount of data in a flash memory system.

The electronic system 2710 may further include an interface 2714 configured to transmit and receive data to and from a communication network. The interface 2714 may be a wired or wireless type. For example, the interface 2714 may include an antenna or a wired or wireless transceiver.

The electronic system 2710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

In an embodiment in which the electronic system 2710 includes equipment capable of performing wireless communication, the electronic system 2710 may be used in a communication system such as CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments of the present invention have been disclosed above for illustrative purposes. Those skilled in the art will appreciate that various modifications, additions and substitutions are possible, without departing from the scope and spirit of the present invention as disclosed in the accompanying claims.

What is claimed is:

1. A semiconductor device comprising:
a through electrode penetrating a substrate such that an end portion of the through electrode protrudes from a surface of the substrate;
a passivation layer covering the surface of the substrate and defining a plug hole that exposes the end portion of the through electrode, a top surface of the end portion of the through electrode corresponding to a bottom surface of the plug hole; and
a barrier plug filling the plug hole.

2. The semiconductor device of claim 1, wherein the passivation layer has a thickness which is greater than a distance from which the end portion of the through electrode protrudes from the surface of the substrate.

3. The semiconductor device of claim 2, wherein the passivation layer includes a first insulation layer that covers the surface of the substrate and extends over sidewalls of the end portion of the through electrode and sidewalls of the barrier plug.

4. The semiconductor device of claim 3, wherein the passivation layer further includes a second insulation layer that is disposed on the first insulation layer to provide a flat surface.

5. The semiconductor device of claim 4,
wherein the first insulation layer includes a silicon oxynitride layer or a silicon nitride layer; and
wherein the second insulation layer includes a silicon oxide layer.

6. The semiconductor device of claim 3, wherein the barrier plug has a top surface which is substantially coplanar with a top surface of the passivation layer.

7. The semiconductor device of claim 3, wherein the barrier plug includes a metal layer that prevents elements contained in the through electrode from being diffused out.

8. The semiconductor device of claim 3, wherein the barrier plug includes a first metal layer and a second metal layer, and a material of the first metal layer is different from a material of the second metal layer.

9. The semiconductor device of claim 8,
wherein the second metal layer includes a plating layer; and
wherein the first metal layer includes a seed layer used in a plating process for forming the second metal layer.

10. The semiconductor device of claim 8,
wherein the second metal layer includes a nickel layer; and
wherein the first metal layer includes a titanium layer or a copper layer.

11. The semiconductor device of claim 8, wherein the first metal layer covers the top surface of the end portion of the through electrode exposed by the plug hole and extends over sidewalls of the passivation layer exposed by the plug hole to have a concave shape.

12. The semiconductor device of claim 2, wherein the barrier plug is aligned with the end portion of the through electrode and has substantially the same diameter as the through electrode.

13. The semiconductor device of claim 2,
wherein the end portion of the through electrode has a cone-shaped configuration or a convex top surface such that an edge region of the end portion of the through electrode is lower than a central region of the end portion of the through electrode; and
wherein the barrier plug has a concave bottom surface such that an edge region of a bottom surface of the barrier plug is lower than a central region of the bottom surface of the barrier plug.

14. The semiconductor device of claim 2, wherein the passivation layer includes an organic material layer or an inorganic material layer.

15. A semiconductor device comprising:
a first through electrode penetrating a first substrate such that an end portion of the first through electrode protrudes from a surface of the first substrate;
a passivation layer covering the surface of the first substrate and defining a plug hole that exposes the end portion of the first through electrode, a top surface of the end portion of the first through electrode corresponding to a bottom surface of the plug hole;
a barrier plug filling the plug hole;
a second substrate stacked on the first substrate; and
a connection terminal connected to the second substrate and coupled with the barrier plug.

16. The semiconductor device of claim 15, wherein the passivation layer has a thickness which is greater than a distance from which the end portion of the first through electrode protrudes from the surface of the first substrate.

17. The semiconductor device of claim 16, wherein the passivation layer includes a first insulation layer that covers the surface of the first substrate and extends over sidewalls of the end portion of the first through electrode and sidewalls of the barrier plug.

18. The semiconductor device of claim 15, wherein the connection terminal includes a conductive bump having a diameter which is greater than a diameter of the barrier plug.

19. The semiconductor device of claim 15, wherein the conductive bump is electrically connected to a second through electrode penetrating the second substrate.

20. A semiconductor device comprising:
a first through electrode penetrating a first substrate such that an end portion of the first through electrode protrudes from a surface of the first substrate;
a passivation layer covering the surface of the first substrate and defining a plug hole that exposes a top surface of the end portion of the first through electrode;
a barrier plug filling the plug hole;
a second substrate stacked on the first substrate; and
a connection terminal connected to the second substrate and coupled with the barrier plug,
wherein the passivation layer has a thickness which is greater than a height of the end portion of the first through electrode, and
wherein the passivation layer includes an insulation layer that covers the surface of the first substrate and extends over sidewalls of the end portion of the first through electrode and sidewalls of the barrier plug.
